(19) United States
(12) Patent Application Publication
(10) Pub. No.: US 2005/0254281 A1
(43) Pub. Date: Nov. 17, 2005

(54) Information recording medium, information recording device and method, information reproduction device and method, information recording/reproduction device and method, computer program, and data structure

(76) Inventors: Takao Sawabe, Saitama (JP); Yukiyoshi Haraguchi, Saitama (JP); Mutsumi Kono, Saitama (JP); Hirotaka Furuta, Saitama (JP); Shinya Sasatani, Saitama (JP); Hayato Watanabe, Saitama (JP); Kyoko Oishi, Saitama (JP)

Correspondence Address: YOUNG & THOMPSON, 745 SOUTH 23RD STREET, 2ND FLOOR, ARLINGTON, VA, 22202, US

(21) Appl. No.: 10/523,700

(22) PCT Filed: Jul. 29, 2003
(86) PCT No.: PCT/JP03/09601

§ 371 Date: Feb. 3, 2005

(30) Foreign Application Priority Data
Aug. 5, 2002 (JP) 2002-227910

(51) Int. Cl. G11C 11/22

(52) U.S. Cl. 365/145

(57) ABSTRACT

In an information recording medium, the position of each bit in the bit arrangement (800b) consisting of a plurality of bits is related to each channel corresponding to the position of each speaker in the speaker arrangement (800a) consisting of a plurality of speakers. By the value of each bit, the channel assignment information (800I) is recorded to indicate whether audio data of a corresponding channel is present. Moreover, a plurality of audio data whose presence is indicated by the channel assignment information is recorded for each channel.

### TECHNICAL FIELD

The present invention relates to information record media such as optical discs relating to recording or reproducing multi-channel audio data, relates to information record apparatuses and methods, relates to information reproduction apparatuses and methods, relates to information record reproduction apparatuses and methods, and relates to data structures.

### BACKGROUND ART

There are various types of multi-channel audio data, such as 2 channels , 3 channels, 4 channels, 5 channels, and 5.1 channels for a general use. Further multi-channel audio data such as more channels are also presented for a theater use or a movie theater use.

In a conventional DVD, for example, based on a DVD audio standard as disclosed in Japanese Patent Application Laid-Open No. 2000-11546, it is possible to record such multi-channel audio data. For example, it is possible to record Lf (Left Front) channel audio data for a left front speaker, Rf (Right Front) channel audio data for a right front speaker and C (Center) channel audio data for a center speaker. Alternatively, it is possible to record Lf audio data for a left front speaker, Lr (Left Rear) channel audio data for a left rear speaker, Rf channel audio data for a right front speaker, Rr (Right Rear) channel audio data for a right rear speaker and C channel audio data for a center speaker. Thereby, multi-channel audio data can be reproduced with the aid of a so-called surround system.

In order to indicate what multi-channel audio data is recorded on each DVD, a channel assignment mode (channel assignment mode) is recorded in the control information. In an object data area, audio data for each channel are arranged according to this channel assignment mode.

More specifically, for example, in a DVD video format, a channel assignment mode of 3 bits is defined in application information. The channel assignment mode indicates audio coding and further indicates the audio channel number and what number each channel is assigned to. For example, if the channel assignment mode is “010b” and the audio coding is a linear PCM, which means that the audio channel number is 2, the audio channel #0 is CH1 (L-ch), the audio channel #1 is CH2 (R-ch). Furthermore, for example, if the channel assignment mode is “111b” and the audio coding is a linear PCM, which means that the audio channel number is 5, the audio channels #0 to #4 are CH1 to CH5, respectively.

Incidentally, sample data of each channel has an appropriate bit length and are arranged alternately with each other. For example, in the case of 16 bit mode and 5 channels, they are arranged in a sequence of channels #0, #1, #2, #3, #4, #0, #1, #2, #3, #4 . . . .

### DISCLOSURE OF INVENTION

In the conventional DVD and the like mentioned above, however, the channel assignment mode must be defined for each speaker arrangement, i.e. for each channel configuration. For this, it is impossible to record or reproduce multi-channel audio data corresponding to a speaker arrangement different from a speaker arrangement defined as a format standard.

On the contrary, in a surround system for commercial use such as for movie theaters, or in a sophisticated surround system for home use, many speakers are arranged two dimensionally in a large room. Furthermore, many speakers are often arranged three dimensionally also in a vertical direction on the ceiling or walls. In the conventional DVD mentioned above, it is impossible to record multi-channel audio data corresponding to such a three dimensional (3D) speaker arrangement or complicated two dimensional (2D) speaker arrangement.

Additionally, it is possible, in theory, to record multi-channel audio data by defining the corresponding channel assignment modes to a variety of complicated speaker arrangements in advance. Nevertheless, it is very difficult in practice, because the channel assignment modes, which exponentially increase, must be defined in advance in order to handle completely the variety of speaker arrangements.

The present invention has been accomplished in view of above problems for example, and aims to provide an information record medium, as well as an information record apparatus and method, showing good flexibility in kinds of speaker arrangements capable of being handled, and capable of recording multi-channel audio data, and provide an information reproduction apparatus and method capable of reproducing such multi-channel audio data, and provide an information record reproduction apparatus capable of recording and reproducing such multi-channel audio data, and provide a computer program for control purpose to make a computer function as the information record apparatus, the information reproduction apparatus or the information record reproduction apparatus, and provide a data structure including a control signal capable of recording multi-channel audio data.

In the information record medium, in order to solve the above problems for example, reproduction control information including channel assignment information in which each bit position in a bit arrangement made of a plurality of bits is assigned to each channel corresponding to each speaker position in a speaker arrangement made of a plurality of speakers, so that each bit value indicates whether or not audio data for each channel corresponding to each bit exists, and a plurality of audio data whose existence is indicated by the channel assignment information and recorded for each channel are recorded.

The information record apparatus, in order to solve the above problems for example, is provided with: a generating device for generating reproduction control information including channel assignment information in which each bit position in a bit arrangement made of a plurality of bits is assigned to each channel corresponding to each speaker position in a speaker arrangement made of a plurality of speakers, so that each bit value indicates whether or not audio data for each channel corresponding to each bit exists; a first recording device for recording the generated reproduction control information into a control information area on an information record medium; and a second recording device for recording a plurality of audio data whose existence is indicated by the channel assignment information into a data area on the information record medium for each channel.

The information record method, in order to solve the above problems for example, is provided with: a generating process of generating reproduction control information including channel assignment information in which each bit position in a bit arrangement made of a plurality of bits is assigned to each channel corresponding to each speaker position in a speaker arrangement made of a plurality of speakers, so that each bit value indicates whether or not audio data for each channel corresponding to each bit exists; a first recording process of recording the generated reproduction control information into a control information area on an information record medium; and a second recording process of recording a plurality of audio data whose existence is indicated by the channel assignment information into a data area on the information record medium for each channel.

The information reproduction apparatus, in order to solve the above problems for example, is an apparatus for reproducing the plurality of audio data from the information record medium according to the present invention mentioned above (including the various aspects thereof), and provided with: a reading device for reading the plurality of audio data and the reproduction control information from the information record medium; an identifying device for identifying channels of the plurality of audio data recorded in the information record medium, on the basis of each bit position in the bit arrangement relating to the channel assignment information included in the read reproduction control information; and a reproducing device for reproducing the plurality of read audio data as a plurality of audio data for the identified each channel.

The information reproduction method, in order to solve the above problems for example, is a method of reproducing the plurality of audio data from the information record medium according to the present invention mentioned above (including the various aspects thereof), and provided with: a reading process of reading the plurality of audio data and the reproduction control information from the information record medium; an identifying process of identifying channels of the plurality of audio data recorded in the information record medium, on the basis of each bit position in the bit arrangement relating to the channel assignment information included in the read reproduction control information; and a reproducing process of reproducing the plurality of read audio data as a plurality of audio data for the identified each channel.

The information record reproduction apparatus, in order to solve the above problems for example, is provided with: a generating device for generating reproduction control information including channel assignment information in which each bit position in a bit arrangement made of a plurality of bits is assigned to each channel corresponding to each speaker position in a speaker arrangement made of a plurality of speakers, so that each bit value indicates whether or not audio data for each channel corresponding to each bit exists; a first recording device for recording the generated reproduction control information into a control information area on an information record medium; a second recording device for recording a plurality of audio data whose existence is indicated by the channel assignment information into a data area on the information record medium for each channel; a reading device for reading the plurality of audio data and the reproduction control information from the information record medium; an identifying device for identifying channels of the plurality of audio data recorded in the information record medium, on the basis of each bit position in the bit arrangement relating to the channel assignment information included in the read reproduction control information; and a reproducing device for reproducing the plurality of read audio data as a plurality of audio data for the identified each channel.

The information record reproduction method, in order to solve the above problems for example, is provided with: a generating process of generating reproduction control information including channel assignment information in which each bit position in a bit arrangement made of a plurality of bits is assigned to each channel corresponding to each speaker position in a speaker arrangement made of a plurality of speakers, so that each bit value indicates whether or not audio data for each channel corresponding to each bit exists; a first recording process of recording the generated reproduction control information into a control information area on an information record medium; a second recording process of recording a plurality of audio data whose existence is indicated by the channel assignment information into a data area on the information record medium for each channel; a reading process of reading the plurality of audio data and the reproduction control information from the information record medium; an identifying process of identifying channels of the plurality of audio data recorded in the information record medium, on the basis of each bit position in the bit arrangement relating to the channel assignment information included in the read reproduction control information; and a reproducing process of reproducing the plurality of read audio data as a plurality of audio data for the identified each channel.

The computer program for a recording control, in order to solve the above problems for example, is a program to control a computer provided for the information record apparatus according to the present invention mentioned above (including the various aspects thereof), and to make the computer function as at least part of the generating device, the first recording device and the second recording device.

The computer program for a reproduction control, in order to solve the above problems for example, is a program to control a computer provided for the information reproduction apparatus according to the present invention mentioned above (including the various aspects thereof), and to make the computer function as at least part of the reading device, the identifying device and the reproducing device.

The computer program for a recording and reproduction control, in order to solve the above problems for example, is a program to control a computer provided for the information record reproduction apparatus according to the present invention mentioned above (including the various aspects thereof), and to make the computer function as at least part of the generating device, the first recording device, the second recording device, the reading device, the identifying device and the reproducing device.

The data structure including a control signal, in order to solve the above problems for example, is provided with: reproduction control information including channel assignment information in which each bit position in a bit arrangement made of a plurality of bits is assigned to each channel corresponding to each speaker position in a speaker arrangement made of a plurality of speakers, so that each bit value indicates whether or not audio data for each channel corresponding to each bit exists, and a plurality of audio data whose existence is indicated by the channel assignment information and recorded for each channel.

The computer program product for a recording control in a medium readable by a computer, in order to solve the above problem for example, tangibly exemplifies program instructions executable by a computer provided for the information record apparatus according to the present invention mentioned above (including the various aspects thereof), makes the computer function as at least part of the generating device, the first recording device and the second recording device.

The computer program product for a reproduction control in a medium readable by a computer, in order to solve the above problem for example, tangibly exemplifies program instructions executable by a computer provided for the information reproduction apparatus according to the present invention mentioned above (including the various aspects thereof), makes the computer function as at least part of the reading device, the identifying device and the reproducing device.

The computer program product for a recording and reproduction control in a medium readable by a computer, in order to solve the above problem for example, tangibly exemplifies program instructions executable by a computer provided for the information record reproduction apparatus according to the present invention mentioned above (including the various aspects thereof), makes the computer function as at least part of the generating device, the first recording device, the second recording device, the reading device, the identifying device and the reproducing device.

At least part of the generating device, the first recording device, the second recording device, the reading device, the identifying device and the reproducing device may be embodied relatively easily, by reading and running the computer program product from a record medium, such as a ROM, a CD-ROM, a DVD-ROM, a hard disk and so on, storing the computer program therein/thereon, or by downloading the computer program product as a carrier wave to the computer via the communication device and running it. More specifically, the computer program product may be made of codes (or instructions readable by a computer) to make the computer function as at least one of the generating device, the first recording device, the second recording device, the reading device, the identifying device and the reproducing device.

The effects and other advantages of the present invention will be more apparent from the following embodiments.

### BRIEF DESCRIPTION OF DRAWINGS

FIG. 1 is a conceptual view illustrating an exemplary channel assignment information recorded in the first embodiment of the information record medium according to the present invention, in which the bit arrangement thereof is assigned to a speaker arrangement (2D arrangement).

FIG. 2 is a conceptual view illustrating an exemplary channel assignment information recorded in the second embodiment of the information record medium according to the present invention, in which the bit arrangement thereof is assigned to a speaker arrangement (3D arrangement).

FIG. 3 is a conceptual view showing in its upper part a schematic plan view of an optical disc structure having a plurality of areas, and in its lower part a conceptual view of an area structure in the radius direction.

FIG. 4 is a conceptual view schematically illustrating a data structure recorded on the optical disc in an example of the information record medium.

FIG. 5 is a conceptual view showing an example of a specific data structure of a logic information file in an example of the information record medium.

FIG. 6 is a conceptual view showing an example of a specific data structure of a data file in an example of the information record medium.

FIG. 7 is a conceptual view showing an example of a specific data structure of music reproduction time length information in the logic information file in an example of the information record medium.

FIG. 8 is a conceptual view showing an example of a specific data structure of constitutional channel number information in the logic information in an example of the information record medium.

FIG. 9 is a conceptual view showing an example of a specific data structure of layer layout information in the logic information file in an example of the information record medium.

FIG. 10 is a conceptual view showing an example of a specific data structure of a channel assignment table in an example of the information record medium.

FIG. 11 is a conceptual view showing a recording sequence of samples of sound data in an example of the information record medium, in association with a bit arrangement on a channel assignment table.

FIG. 12 is a conceptual view showing a channel assignment table for a floor level and a channel assignment table for a ceiling level, as a specific example of embodiment of the information record medium.

FIG. 13 is a conceptual view showing actual bit arrangement in two channel assignment tables shown in FIG. 12.

FIG. 14 is a conceptual view showing a data structure when the sample data in the specific example of FIG. 13 is arranged as stream data in the data area.

FIG. 15 is a conceptual view showing a data structure in a modification of the specific example of FIG. 13.

FIG. 16 is a block diagram illustrating an example of the information record reproduction apparatus according to the present invention.

### BEST MODE FOR CARRYING OUT THE INVENTION

Now, embodiments of the present invention will be explained, on the basis of drawings.

(First Embodiment of Information Record Medium)

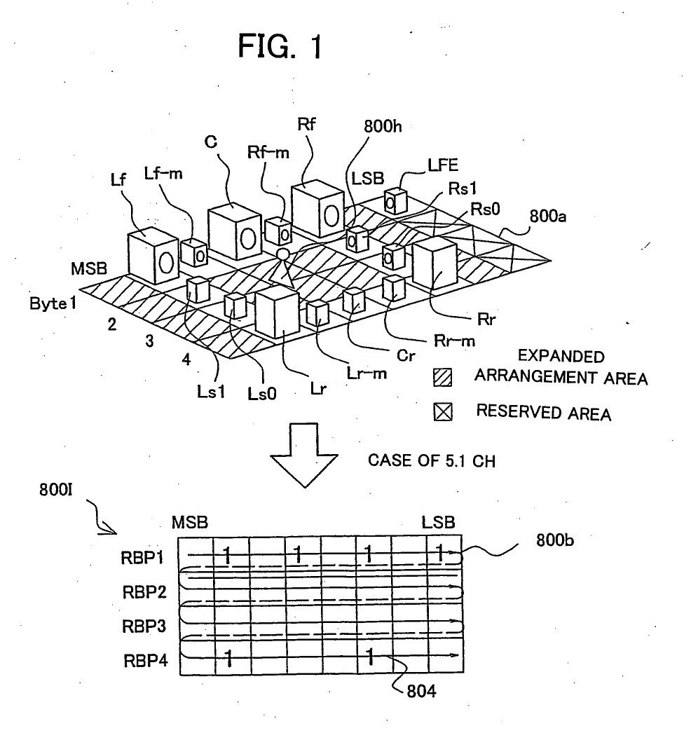

Firstly, the first embodiment of the information record medium according to the present invention will be explained with reference to FIG. 1. FIG. 1 conceptually shows an assignment of a bit arrangement to a speaker arrangement (two dimensional arrangement), in an exemplary channel assignment information recorded into the information record medium of this embodiment.

For example in this embodiment, the information record medium may be an optical disc capable of optically only reproducing information, or capable of recording and reproducing information.

Into the information record medium of this embodiment, (i) reproduction control information including channel assignment information in which each bit position in a bit arrangement consisting of a plurality of bits arranged one dimensionally or two dimensionally is assigned to each channel corresponding to each speaker position in a speaker arrangement consisting of a plurality of speakers arranged one dimensionally, two dimensionally or three dimensionally, so that a binary value of each bit indicates whether or not audio data for each channel corresponding to each bit exists and (ii) a plurality of audio data whose existence is indicated by the channel assignment information and recorded for each channel are recorded.

These reproduction control information and audio data are recorded into a data area which is a main part of an optical disc. Incidentally, the audio data may be recorded with contents data such as other video data or sub-picture data.

As shown in FIG. 1, in the channel assignment information 800I, each bit position in a bit arrangement 800b consisting of a plurality of bits arranged two dimensionally (see lower part of FIG. 1) is assigned to each channel corresponding to each speaker position in a speaker arrangement 800a consisting of a plurality of speakers Lf, Lf-m, C, . . . , and so on arranged two dimensionally on a floor (see upper part of FIG. 1).

More specifically, RBP (Relative Byte Pointer) #1, i.e. the first row, in a bit arrangement 800b of 8 bits by 4 rows, arranged in a sequence shown by an arrow 804 in a bit arrangement 800b at the lower part of FIG. 1, is assigned to a front side of the speaker arrangement 800a on the basis of an audience (see upper part of FIG. 1). RBP #4, i.e. the fourth row, is assigned to a rear side of the speaker arrangement 800a on the basis of the audience 800h. A MSB (Most Significant Bit) side of the bit arrangement 800b is assigned to a left side of the speaker arrangement 800a on the basis of the audience 800h. Furthermore, a LSB (Least Significant Bit) side of the bit arrangement 800b is assigned to a right side of the speaker arrangement 800a on the basis of the audience 800h. Each row made of 8 bits is defined as 1 byte , so that each row number is indicated by the RBP.

LSBs positioned at each right end of the second to fourth rows of the bit arrangement 800b are not assigned to any speaker position of the speaker arrangement 800a, and thereby not used. However, an LSB on the first row, as “a bit on a predetermined position” of the bit arrangement 800b, indicates whether or not audio data of a channel not corresponding to any speaker position of the speaker arrangement 800a exists. Particularly in this example, the LSB on the first row is assigned to a channel for a super woofer (LFE). Similarly, unused LSBs on the second to fourth rows may be defined to indicate whether or not audio data of channels not corresponding to any speaker position of the speaker arrangement 800a exists, or may include any other information recorded therein.

Furthermore, as shown in FIG. 1, to the second and third rows of the speaker arrangement 800a, side speakers Ls1, Ls2, Rs1, Rs2 are assigned both side of the audience 800h. Therefore, this embodiment is applicable to such a speaker arrangement including these side speakers.

Hatched squares among the plurality of squares indicating each speaker position in the speaker arrangement 800a shown in the upper part of FIG. 1 are expanded allocation areas. The expanded allocation areas are positioned at MSBs positioned at left side on every row of the bit arrangement 800b, and near the center area around the audience 800h. Speakers are not usually assigned to these positions. However, it is not difficult to handle a speaker arrangement in which speakers are assigned to each expanded allocation area, without a new definition, if the bit arrangement 800b of the channel assignment information 800I of this embodiment is used. For example, in the case that audio data of a channel corresponding to a left front outside speaker positioned outside of a left front speaker Lf is recorded, information indicating whether or not the audio data corresponding to the left front outside speaker exists may be recorded at the MSB on the first row in the expanded allocation area.

Thus, particularly in this embodiment, the bit arrangement 800b is made of a plurality of bits arranged two dimensionally of 8 bit as a predetermined bit number on each row by 4 rows as a predetermined row number, while the speaker arrangement 800a is made of a plurality of speakers arranged on a plane corresponding to the two dimensional arrangement of a plurality of bits.

However, in this embodiment, 8 bits and 4 rows constructing the bit arrangement 800b are taken as an example. So, 4 bits by 2 rows may be taken, or 16 bits by 8 rows may be taken, instead of the aforementioned 8 bits by 4 rows. Preferably, at least one of a predetermined bit number constructing one row and a predetermined row number is variable.

In the case that audio data of a plurality of channels of a multi-channel type such as 5.1 channels is recorded into the information record medium in this embodiment, the channel assignment information 800I having bit values specifically shown in the lower part of FIG. 1 in the bit arrangement 800b is recorded as the channel assignment information in the reproduction control information with this audio information. Then, when the information record medium is reproduced, referring to the channel assignment information 800I makes it possible to specify what channel construction the audio data has, or what speaker arrangement the audio data corresponds to.

Specifically, in FIG. 1, if each bit value is “1” in the bit arrangement 800b, it indicates that the corresponding speaker exists in the speaker arrangement 800a, and thereby the audio data of the corresponding channel exists. On the other hand, if each bit vale is “0”, it indicates that the corresponding speaker does not exist in the speaker arrangement 800a, and thereby the audio data of the corresponding channel does not exist. Incidentally, bit values other than “1” in the bit arrangement 800b are not shown in FIG. 1 for the simplicity, but remain values other than “1” are all “0” actually.

Therefore in this embodiment, which is a case showing 5.1 channels, the second, fourth and sixth values on the first row of the bit arrangement 800b are defined as “1” for each, and the second and sixth values on the fourth row are defined as “1” for each, and the LSB on the first row is defined as “1”, and remain bit values are defined as “0” for each, in FIG. 1. These bit values make it possible to identify that the audio data of 5.1 channels corresponding to speakers Lf, C, Rf, Lr, Rr and LFE is recorded.

Incidentally, if each bit value is “0”, on the contrary to the above case, it may indicate that the audio data of the corresponding channel exists, and if each bit value is “1”, it may indicate that the audio data of the corresponding channel does not exist.

Thus, existence of a plurality of audio data is indicated by each bit of the bit arrangement 800b, and the plurality of audio data are recorded onto the information record medium for each channel. In this case, the audio data is typically made of various types of digital audio data sampled with an appropriate sampling frequency.

As mentioned above, according to this embodiment, since each bit position in the bit arrangement 800b corresponds to each speaker position in the speaker arrangement 800a, information required to indicate each speaker position or existence thereof in the speaker arrangement 800a can be remarkably reduced. If a conventional channel assignment mode is used, an amount of the information required for the channel assignment mode increases exponentially with the speaker number, in order to indicate each speaker position or existence thereof in the speaker arrangement 800a as shown in the upper part of FIG. 1.

Furthermore, in this embodiment, although a case of 8 bits by 4 rows is shown for the bit arrangement 800b, bit number constructing each row and row number in the bit arrangement 800b may be freely increased or decreased. That is, if information indicating a bit number constructing each row or row number is included with the channel assignment information within the reproduction control information, referring to these information in reproducing the information record medium makes it possible to assign each audio data to each speaker without any deficiency. Even in the case that a quite new speaker arrangement is taken or the channel assignment corresponding to the new speaker arrangement is performed, the channel assignment mode is free from being newly defined as seen in the conventional art, so that the new speaker arrangement is handled easily.

Thus, according to this embodiment, there is a great flexibility in kinds of the speaker arrangement capable of being handled.

Incidentally, the bit arrangement and the speaker arrangement are a two dimensional arrangement for each in this embodiment, but they may be one dimensional arrangement, for example in the case that only a front speaker is considered. Also in this case, it is possible to provides a good flexibility and obtain a substantial effect, in comparison with a case that a simple speaker arrangement is defined by means of a conventional channel assignment mode.

Particularly in this embodiment, since the channel assignment information 800I is made of a channel assignment table to assign the speaker arrangement 800a with the bit arrangement 800b, as shown in the lower part of FIG. 1, referring to the channel assignment table in reproducing the information record medium makes it possible to identify the channel of the audio data easily and quickly.

Preferably in this embodiment, a plurality of audio data is packed or packetized on the information record medium. Furthermore, the plurality of audio data is arranged in a sequence corresponding to an arrangement sequence of a plurality of bits in each pack or each packet by a unit of one or more samples. The “a sequence corresponding to . . . ” herein may be counted from a left side of the speaker arrangement 800a shown in FIG. 1 for example, or may be counted from a right side, or may be counted from a front side or may be counted from a rear side. For example, the bit arrangement sequence shown by the arrow 804 in the bit arrangement 800b of the lower part of FIG. 1 may be an audio data recording sequence in a pack or packet as it is. In any sequence, it can be identified what channel the audio data of each sample unit corresponds to in reproducing the information record medium, insofar as the sequence obeys a predetermined rule, and thereby no problem arises. Furthermore, the “sample unit” may be any arbitrary sample unit, such as 8 bits, 16 bits, 24 bits and so on.

Additionally, in the case that the audio data is packed or packetized as such, it is preferable that no space or area to store the audio data, whose existence is not indicated because the bit value in the bit arrangement 800b is “0”, is prepared in the pack or packet, while only the audio data, whose existence is indicated because the bit value in the bit arrangement 800b is “1”, is arranged in the pack or packet by a sample unit without vacant spaces. Thereby, it is possible to reduce the data area to record the audio data.

(Second Embodiment of Information Record Medium)

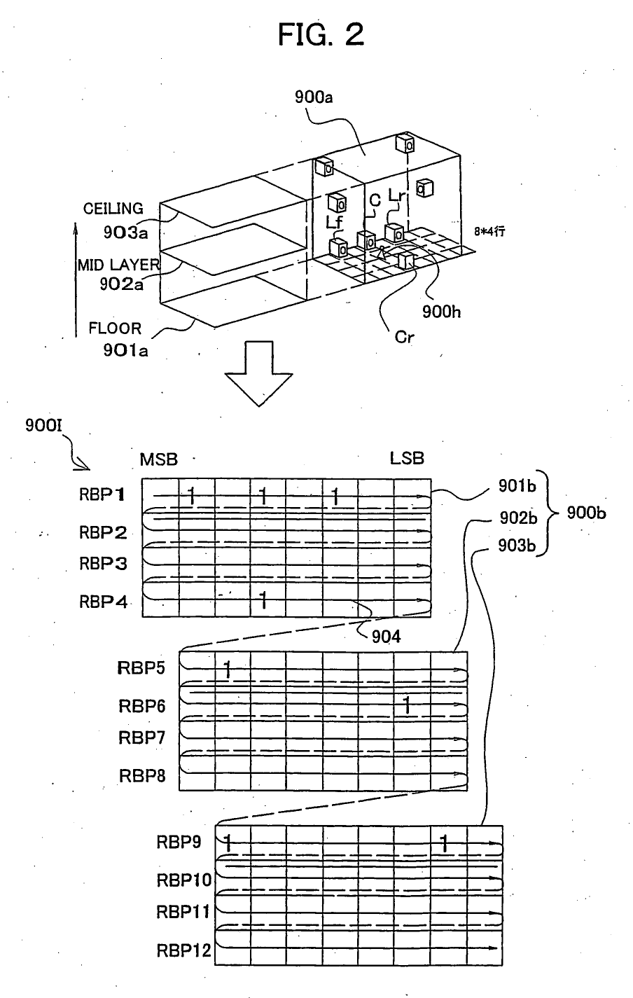

The second embodiment of the information record medium according to the present invention will be explained, with reference to FIG. 2. FIG. 2 conceptually shows an assignment of a bit arrangement to a speaker arrangement (three dimensional arrangement), in an exemplary channel assignment information recorded into the information record medium of this embodiment.

For example in this embodiment, the information record medium may be an optical disc capable of optically only reproducing information, or capable of recording and reproducing information.

In the second embodiment, the speaker arrangement is made of a plurality of speakers arranged three dimensionally. A plurality of bits in a bit arrangement constructing the channel assignment information includes a plurality of partial bit arrangements. Each of partial bit arrangements is made of a plurality of bits arranged two dimensionally with a predetermined bit number for each row over a predetermined number of rows and assigned to a plurality of channels corresponding to speakers arranged on a plane of the same height for each partial bit arrangement from among a plurality of speakers arranged three dimensionally. A plurality of partial bit arrangements exists as many as the planes of different heights. Other parts of the construction are the same as in the case of the aforementioned first embodiment.

That is, in the second embodiment as shown in FIG. 2, the channel assignment information 900I is made of a bit arrangement 900b including three two-dimensional bit arrangements as “partial bit arrangements” similar to the bit arrangement 800b shown in the lower part of FIG. 1 in the first embodiment, for a floor level, a mid layer level and a ceiling level. On the other hand, the speaker arrangement 900a arranged three dimensionally includes a speaker arrangement 901a arranged two dimensionally on the floor level, a speaker arrangement 902a arranged two dimensionally on the mid layer level and a speaker arrangement 903a arranged two dimensionally on the ceiling level.

In the channel assignment information 900I, each bit position in the partial bit arrangement 901b in the bit arrangement 900b (see lower part of FIG. 2) is assigned to each channel corresponding to each speaker position in the speaker arrangement 901a arranged two dimensionally on the floor level (see upper part of FIG. 2). Furthermore, each bit position in the partial bit arrangement 902b in the bit arrangement 900b (see lower part of FIG. 2) is assigned to each channel corresponding to each speaker position in the speaker arrangement 902a arranged two dimensionally in the mid layer level (see upper part of FIG. 2). Furthermore, each bit position in the partial bit arrangement 903b in the bit arrangement 900b (see lower part of FIG. 2) is assigned to each channel corresponding to each speaker position in the speaker arrangement 903a arranged two dimensionally in the ceiling level (see upper part of FIG. 2).

A row of RBP#1, i.e. the first row, of the partial bit arrangement 901b designated by RBPs #1 to #4, in the bit arrangement 900b of 8 bits by 4 rows by 3 levels, arranged in a sequence shown by an arrow 904 in the bit arrangement 900b at the lower part of FIG. 2, is assigned to a front side of the speaker arrangement 901a on the basis of a audience 900h at the floor level (see upper part of FIG. 2). Then, in the floor level, each bit position is assigned similarly to the first embodiment.

A row of RBP#5, i.e. the first row, of the partial bit arrangement 902b designated by RBPs #5 to #8 in the bit arrangement 900b is assigned to a front side of the speaker arrangement 902a on the basis of the audience 900h at the mid layer level (see upper part of FIG. 2). Then, a row of RBP#8, i.e. the fourth row, is assigned to a rear side of the speaker arrangement 902a on the basis of the audience 900h at the mid layer level. A MSB side of the bit arrangement 902b is assigned to a left side of the speaker arrangement 902a on the basis of the audience 900h at the mid layer level. Furthermore, an LSB side of the bit arrangement 902b is assigned to a right side of the speaker arrangement 902a on the basis of the audience 900h at the mid layer level.

A row of RBP#9, i.e. the first row, of the partial bit arrangement 903b designated by RBPs #9 to #12 in the bit arrangement 900b is assigned to a front side of the speaker arrangement 903a on the basis of the audience 900h at the ceiling level (see upper part of FIG. 2). Then, a row of RBP#12, i.e. the fourth row, is assigned to a rear side of the speaker arrangement 903a on the basis of the audience 900h at the ceiling level. A MSB side of the bit arrangement 903b is assigned to a left side of the speaker arrangement 903a on the basis of the audience 900h at the ceiling level. Furthermore, an LSB side of the bit arrangement 903b is assigned to a right side of the speaker arrangement 903a on the basis of the audience 900h at the ceiling level.

Incidentally, an assignment relationship between the bit arrangement and the speaker arrangement is not limited to those mentioned above. For example, a bit portion designated by RBPs #1 to #4 may be assigned to the speaker arrangement at the ceiling level, and a bit portion designated by RBPs #9 to #12 may be assigned to the speaker arrangement at the floor level.

Thus, this embodiment provides good flexibility in kinds of the speaker arrangement capable of being handled. In particular, this embodiment is applicable to multiple channels compatible with a plurality of speakers arranged three dimensionally for a theater or movie theater for example.

Particularly in this embodiment, the reproduction control information including such a channel assignment information 900I further includes total channel number information to indicate a total number of channels, layer information to indicate a total number of levels or planes with difference heights on which speakers can be arranged three dimensionally, and layer constitution information to indicate whether or not at least one speaker is arranged on each plane or each level.

Including these kinds of information makes it possible to identify whether or not the audio data of the channel corresponding to each speaker exists, and identify the recording sequence of the existing audio data, even in the case that a speaker is positioned at any position in the speaker arrangement 900a arranged three dimensionally as shown in the upper part of FIG. 2. That is, referring to the total channel number information, the layer information and the layer constitution information in addition to the channel assignment information 900I makes it possible to reproduce the audio data, which is recorded in the information record medium, having a complicated multiple channels compatible with a 3D speaker arrangement without any difficulty.

Incidentally, the “layer information” among these kinds of information may be a flag of 1 bit for each level. For example, if there are an upper level, a mid level and a lower level, the flag value shall be “1”, otherwise “0”.

(Embodiment of Information Record Apparatus)

Now, an explanation will be made on an embodiment of the information record apparatus according to the present invention.

The information record apparatus of this embodiment is provided with: a generating device for generating reproduction control information including channel assignment information in which each bit position in a bit arrangement made of a plurality of bits arranged one dimensionally or two dimensionally is assigned to each channel corresponding to each speaker position in a speaker arrangement made of a plurality of speakers arranged one dimensionally, two dimensionally or three dimensionally, so that a binary value of each bit indicates whether or not audio data of the channel corresponding to each bit exists ; a first recording device for recording the generated reproduction control information into a control information area on a information record medium; and a second recording device for recording a plurality of audio data whose existence is indicated by the channel assignment information into a data area on the information record medium for each channel.

According to the information record apparatus of this embodiment, the generating device may include a CPU and generates the reproduction control information including the channel assignment information explained with reference to FIG. 1 and FIG. 2 in the first or second embodiment of the information record medium according to the present invention. The first recording device records the generated reproduction control information into the control information area on the information record medium such as an optical disc. The second recording device records a plurality of audio data whose existence is indicated by the channel assignment information into the data area on the information record medium for each channel. For example, the first and second recording devices may include the CPU, an encoder, a formatter, an optical pickup and so on, for optically recording the reproduction control information including the channel assignment information and the audio data onto the information record medium. Alternatively, the first and second recording devices may include the CPU, the encoder, the formatter, a cutting device and so on, for recording the reproduction control information including the channel assignment information and the audio data onto the information record medium with cutting.

Therefore, using the information record apparatus of this embodiment makes it possible to record information onto the first or second embodiment of the information record medium according to the present invention mentioned above.

Incidentally, the information record apparatus can take various aspects, corresponding to various aspects of the information record medium according to the present invention mentioned above.

Additionally, the information record apparatus of the aforementioned embodiment can be realized relatively easily, by running a computer program for record control to make a computer function as the information record apparatus. Specifically, various devices including the generating device, the first recording device, the second recording device and so on may be operated by downloading the program to make the computer function as the information record apparatus into one computer via a communication network or loading the program from the record medium such as a CD or a DVD, and then running this program.

(Embodiment of Information Reproduction Apparatus)

Now, an explanation will be made on an embodiment of the information reproduction apparatus according to the present invention.

The information reproduction apparatus of this embodiment is an information reproduction apparatus for reproducing the plurality of audio data from the first or second embodiment of the information record medium according to the present invention mentioned above (including its various aspects), and is provided with: a reading device for reading the reproduction control information and the plurality of audio data from the information record medium; an identifying device for identifying channels of the plurality of audio data recorded in the information record medium on the basis of each bit position in the bit arrangement relating to the channel assignment information included in the read reproduction control information; and a reproducing device for reproducing the plurality of read audio data as a plurality of audio data for the identified each channel.

According to the information record apparatus of this embodiment, the reading device, which may include an optical pickup, a decoder and so on, reads the channel reproduction control information including the channel assignment information explained with reference to FIG. 1 and FIG. 2 in the first or second embodiment of the information record medium according to the present invention mentioned above, from the information record medium such as an optical disc. The identifying device, which may include a CPU and the like, identifies channels of a plurality of audio data recorded in the information record medium, by referring each bit position in the bit arrangement relating to the channel assignment information included in the read reproduction control information. The reading device reads a plurality of audio data, before or after the channel identification by the identifying device. The reproducing device, which may include the CPU, the decoder and the like, reproduces the plurality of audio data read at the reading device, as a plurality of audio data for each channels identified at the identifying device.

Therefore, using the information reproduction apparatus of this embodiment makes it possible to reproduce the first or second embodiment of the information record medium according to the present invention mentioned above.

Incidentally, the information reproduction apparatus can also take various aspects, corresponding to various aspects of the information record medium according to the present invention mentioned above.

Additionally, the information reproduction apparatus of this embodiment mentioned above can be realized relatively easily by running a computer program for reproduction control to make a computer function as the information reproduction apparatus. Specifically, various devices including the reading device, the identifying device, the reproducing device and so on may be operated by downloading a program to make a computer function as the information reproduction apparatus into one computer via a communication network, or loading from the record medium such as a CD, a DVD, and then running this program.

(Embodiment of Information Record Reproduction Apparatus)

Now, an explanation will be made on an embodiment of the information record reproduction apparatus according to the present invention.

The information record reproduction apparatus of this embodiment is provided with: a generating device for generating reproduction control information including channel assignment information in which each bit position in the bit arrangement made of a plurality of bits arranged one dimensionally or two dimensionally is assigned to each channel corresponding to each speaker position in the speaker arrangement arranged one dimensionally, two dimensionally or three dimensionally, so that a binary value of each bit indicate whether or not audio data of the each channel corresponding to each bit exists; a first recording device for recording the generated reproduction control information into a control information area on an information record medium; and a second recording device for recording a plurality of audio data whose existence is indicated by the channel assignment information into a data area on the information record medium for each channel. Furthermore, the information record reproduction apparatus is further provided with: a reading device for reading the plurality of audio data and the reproduction control information from the information record medium; the identifying device for identifying channels of the plurality of audio data recorded in the information record medium on the basis of each bit position in the bit arrangement relating to the channel assignment information included in the read reproduction control information; and a reproducing device for reproducing the plurality of read audio data as a plurality of audio data for the identified each channel.

Thus, the information record reproduction apparatus of this embodiment has both of the structure of the embodiment of the information record apparatus according to the present invention mentioned above and the structure of the embodiment of the information reproduction apparatus according to the present invention mentioned above. Therefore, using the information record reproduction apparatus of this embodiment makes it possible to record and reproduce information effectively onto or from the first or second embodiment of the information record medium according to the present invention mentioned above.

Incidentally, the information record reproduction apparatus according to the present invention can also take various aspects, corresponding to various aspects of the information record medium according to the present invention mentioned above.

Additionally, the information record reproduction apparatus of this embodiment mentioned above can be realized relatively easily by running a computer program for record reproduction control to make a computer function as the information record reproduction apparatus. Specifically, various devices including the generating device, the fist recording device, the second recording device, the reading device, the identifying device, the reproducing deice and so on may be operated by downloading a program to make a computer function as the information record reproduction apparatus into one computer via a communication network, or loading the program from the record medium such as a CD or a DVD, and then running this program.

As explained above, in each embodiment of the present invention, the reproduction control information including the channel assignment information having the bit arrangement corresponding to the speaker arrangement is recorded into the information record medium such as an optical disc. The information record apparatus or the information record reproduction apparatus such as an optical disc recorder or a cutting device includes the generating device for generating such a channel assignment information and the first recording device for recording this information. The information record method or the information record reproduction method includes a generating process of generating such a channel assignment information and the first recording process of recording this information. The information reproduction apparatus or the information record reproduction apparatus such as an optical disc player includes the identifying device for identifying channels of each audio data on the basis of the channel assignment information. The information reproduction method or the information record reproduction method includes an identifying process of identifying channels of each audio on the basis of the channel assignment information. Furthermore, the data structure including the control signal is provided with the reproduction control information including the channel assignment information. Therefore, each embodiment of the present invention provides a remarkable flexibility in kinds of the speaker arrangement capable of being handled, including a complicated speaker arrangement arranged two dimensionally or three dimensionally.

These effects and other advantages of this embodiment will be more apparent from the following examples.

Various examples of the present invention will be explained, with reference to drawings.

(Example of Information Record Medium)

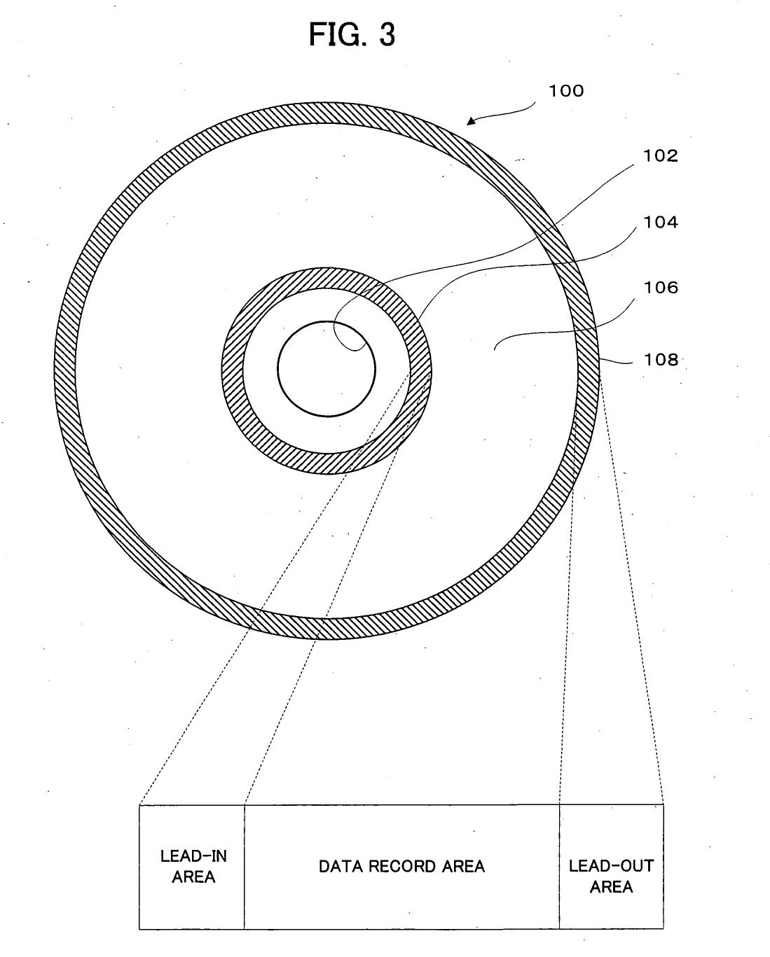

With reference to FIG. 3 to FIG. 15, an explanation will be made on an example of the information record medium according to the present invention. In this example, the information record medium according to the present invention is applied to a recordable (writable) and reproducible (readable) optical disc.

Firstly with reference to FIG. 3, an explanation will be made on a fundamental structure of the optical disc of this embodiment. FIG. 3 illustrates a structure of the optical disc having a plurality of areas as a schematic planar view in the upper part of the figure, and illustrates an area structure in a radius direction as a conceptual view in the lower part of the figure corresponding to the plan view of the upper part.

As shown in FIG. 3, the optical disc 100 is recordable (writable) in various recording formats such as an magneto-optical format or a phase change format allowing one or more recording (writing). The optical disc 100 has a lead-in area 104, a data area 106 and a lead-out area 108 disposed around a center hole 102 sequentially from inward to outward on a recording surface of a disc whose diameter is about 12 cm similar to a DVD. In each area, groove tracks and land tracks are alternately formed spirally or concentrically around the center hole 102, for example. These groove tracks may be wobbled. Furthermore, pre-pits may be formed one or both of these tracks. Incidentally, the present invention is not limited to the optical disc having three areas mentioned above.

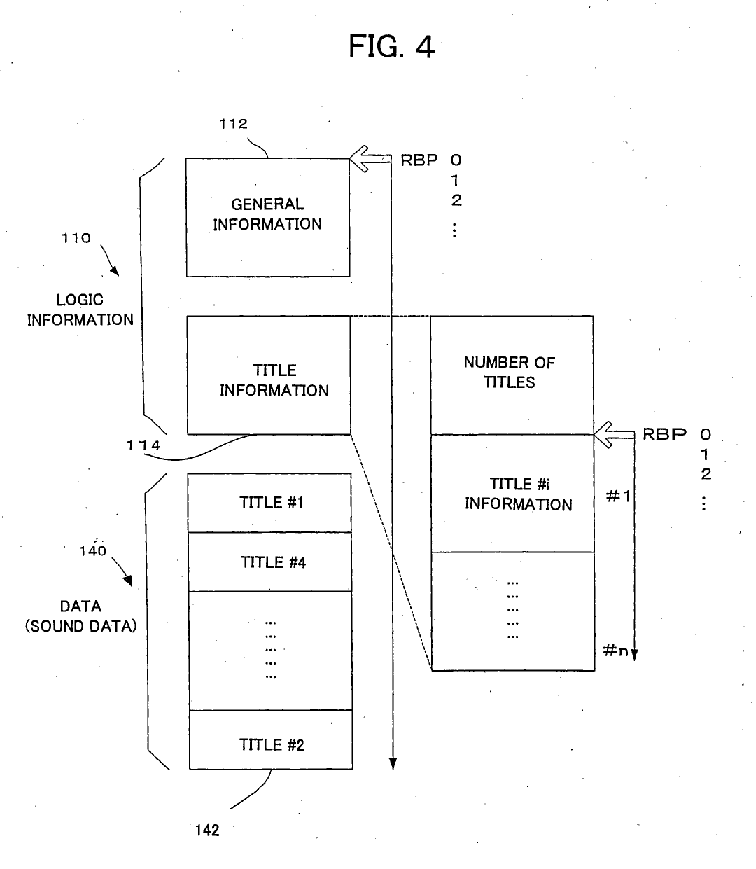

Now, with reference to FIG. 4, an explanation will be made on a structure of data recorded on the optical disc 100. FIG. 4 illustrates schematically shows the structure of the data recorded on the optical disc 100.

In the following explanation, the “title” means a large logical unit of contents, such as one piece of music, one music album, one movie, one TV program and so on.

In FIG. 4, the optical disc 100 includes as its logical structure, a logic information file 110 for storing various logic information, and a data file 140 for storing data such as multi-channel audio data (sound data). The logic information file 110 may be recorded in the data record area 106 shown in FIG. 3, and may be read before the audio data and the like in the data file 140 is reproduced. On the other hand, the data file 140 may be also recorded in the data record area 106 shown in FIG. 3, so that data such as audio data stored therein is reproduced on the basis of various logic information to control the reproduction included in the logic information 110.

The logic information file 110 stores general information 112 and title information 114 therein. Preferably, RBPs (Relative Byte Pointers) #0, #1, #2 . . . are assigned from a head of the general information 112. Thereby, the head position of the general information 112 or the head position of the tile information 114 can be identified by RBPs as pointers, even if the logic information file 110 is variable in its size or the data file 114 is variable in its size.

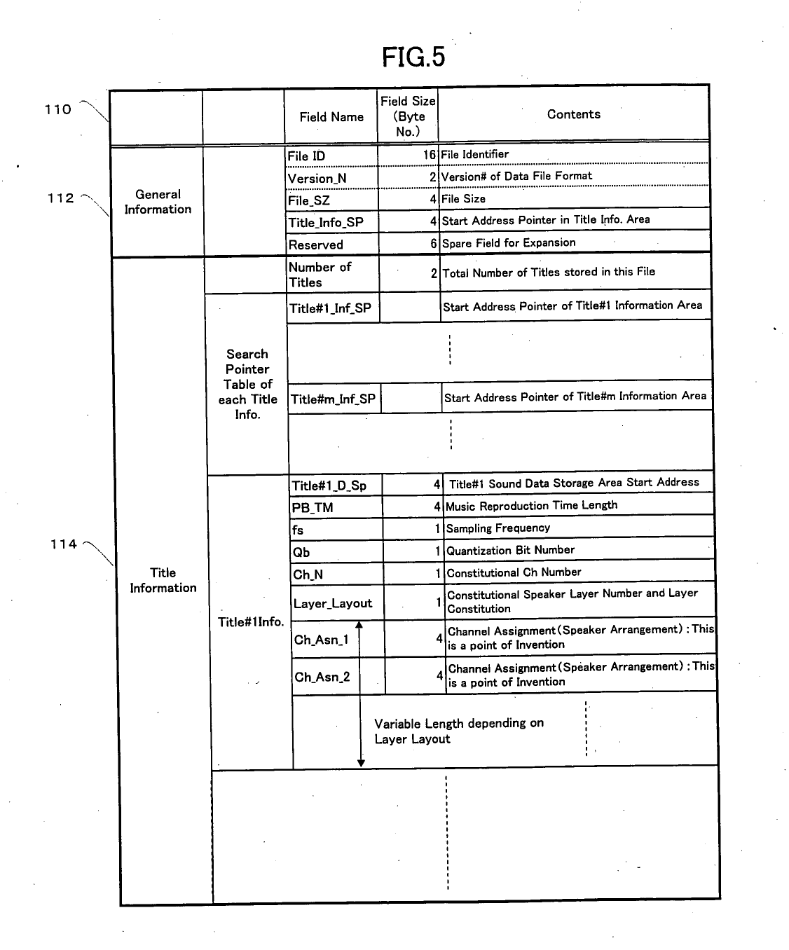

The title information 114 further includes information unique to each title such as total title number information (Number of Titles information), title #i information and so on (i=1, 2, . . . ). Preferably, RBPs #0, #1, #2, . . . is assigned from a head of each title information. Thereby, the head position of each title information can be identified by RBPs as pointers, even if the title number is variable or the data length of each title information is variable. The logic information file 110 will be discussed later in detail, with reference to FIG. 5.

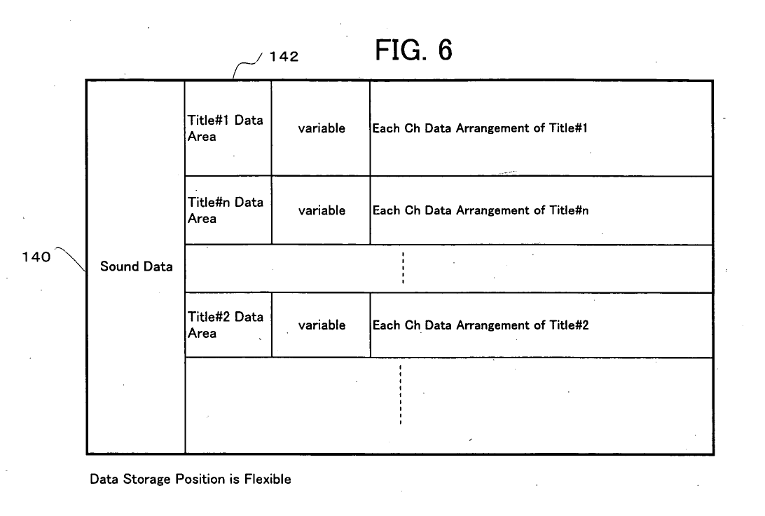

The data file 140 stores title #i data 142 therein for each title #i. The data file 140 will be discussed later in detail, with reference to FIG. 6.

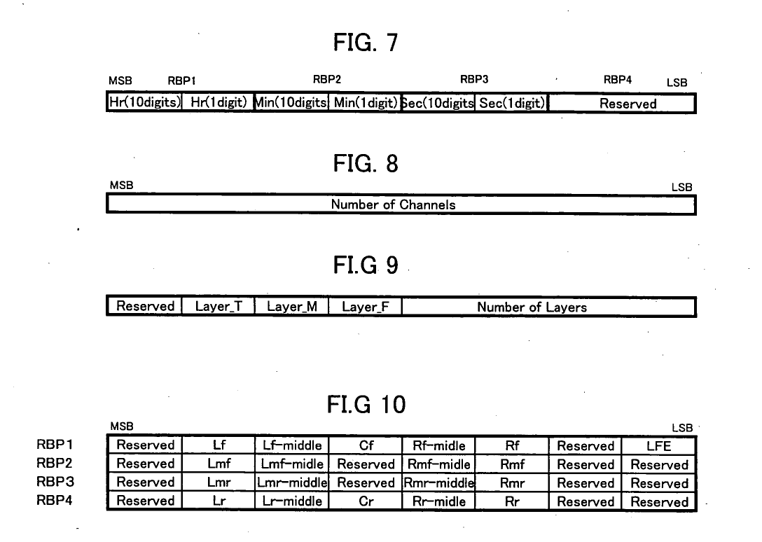

Now, an explanation will be made on the detail of various logic information or sound data stored into the logic information file 110 or the data file 140, with reference to FIG. 5, and FIG. 6 to FIG. 10. FIG. 5 conceptually illustrates an exemplary specific data structure of the logic information file, and FIG. 6 conceptually illustrates an exemplary specific data structure of the data file. FIG. 7 conceptually illustrates an exemplary specific data structure of music reproduction time length information in the logic information file, FIG. 8 conceptually illustrates an exemplary specific data structure of constitutional channel number information in the logic information file, and FIG. 9 conceptually illustrates an exemplary specific data structure of layer layout information in the logic information file. FIG. 10 conceptually illustrates an exemplary specific data structure of the channel assignment table.

As shown in FIG. 5, the logic information file 110 stores the general information 112 and the title information 114 therein, as an example of the “reproduction control information” according to the present invention.

As shown in FIG. 6, the data file 140 stores therein the sound data as an example of the “audio data” according to the present invention, into data areas for each title (title #i data areas), for each title number. Particularly, the sound data relating to each title is basically freely selected or variable, that is, the sound data may be of any channel structure or any multi-channel structure, for example, may be of stereo or surround. There is no need to define a data arrangement way for each channel structure, although such a definition is necessary in the conventional channel assignment mode. That is, the title information 114 discussed below (the channel assignment information and the like in particular) allows to simply identify what channel structure the sound data has, almost no matter what the channel structure the sound data has. An sound data arrangement way of each channel of each title #i is defined in association with the channel assignment table, as discussed later in detail. Additionally, as shown in FIG. 6, positions or sequences of storing the sound data of each title are variable.

Again in FIG. 5, the general information 112 includes field ID information, version number information (version N information), file size information (file SZ information), and title information start address pointer information (tile info SP information). Furthermore, the general information 112 has an auxiliary field for expansion.

The field ID information has a field size of 16 bytes, and records an identifier indicating a file data format of the file, for example by means of ASCII characters or the like.

The version N information has a field size of 2 bytes, and records a version number of the file, for example according to the following rule.
0090h: version 0.9
0100h: version 1.0
0110h: version 1.1

Incidentally, a code “h” in the aforementioned bit value “xxxxh” means that the value is based on hexadecimal notation (hereinafter the same).

The file SZ information has a field size of 4 bytes, and records an entire size of the file (i.e. a total size of “the general information 112+the title information 114+the sound data 140”) with a total byte number from the file head.

The title info SP information has a field size of 4 bytes, and records a start address of a record area of the title information 114 to be stored in the file, with a relative byte value (i.e. RBP value) from the file head.

The title information 114 includes the title total number information, a search pointer table of each title information, and the title #i information.

The title total number information has a field of 2 bytes, and records the total title number (music numbers) to be stored in the file. For example, if the total title number is “5”, it is recorded as “00005h”. After then, in the record area for the title information 114, an area for title #i information of each title for the total title number recorded by this title total number information exists.

The search pointer table of each title information includes the title #i info SP information for that title total number. Furthermore, this title #i info SP information records the start address of the record area of the title #i information to be stored in the file, with the relative byte value (i.e. RBP value) from the file head.

Each title #i information has title #i data start address pointer information (title #i D Sp information), music reproduction time length information (PB TM information), sampling frequency information (fs information), quantization bit number information (Qb information), constitutional channel number information (Ch N information), layer layout information, channel assignment #1 information (Ch Asn 1 information), channel assignment #2 information (Ch Asn 2 information) and so on. Incidentally, depending on contents of the layer layout information, the number of the channel assignment #j information (Ch Asn j information) is set as variable (j=1, 2, . . . ).

The title #i D Sp information has a field size of 4 bytes, and records the start address of the sound data area of the title #i, with the relative byte value (i.e. RBP value) from the file head.

The PB TM information has a field size of 4 bytes, and records a reproduction time length of a music corresponding to each title for each predetermined digit from a MSB side to a LSB side by unit of “time:minute:second”, as shown in FIG. 7 for example. In this case, a binary data is recorded for each digit.

The fs information has a field size of 1 byte, and records the sampling frequency of the sound stream data of title #i, according to the following rule for example.

Incidentally, in this example, sampling frequencies for each channel of one title are the same.
00h: 44.1 kHz
01h: 88.2 kHz
02h: 176.4 kHz
10h: 48 kHz
11h: 96 kHz
12h: 192 kHz
Other values: reserved

The Qb information has a field size of 1 byte , and records the quantization bit number of the sound stream data of title #i, according to the following rule for example.
00h: 16 bits
01h: 20 bits
02h: 24 bits
Other values: Reserved

The Ch N information has a field size of 1 byte , and records a total number of constitutional channels of title #i (i.e. a total channel number over all layers or all levels of the speaker arrangement), as exemplified in FIG. 8 for example. Herein, channel for the LFE is also counted as one channel. Therefore, so-called “5.1 channels” are defined as “6 channels” herein.

Thus in this example, the Ch N information (see FIG. 8) serves as an example of the “total channel number information to indicate a total channel number” according to the present invention.

The layer layout information has a field size of 1 byte , and records the constitutional speaker layer number and the layer constitution of title #i, as exemplified in FIG. 9, for example.

Herein, the “constitutional speaker layer number” becomes “1” in the first embodiment shown in FIG. 1, and becomes “3” in the second embodiment shown in FIG. 2. Thus in this example, the information corresponding to lower 4 bits of the layer layout information (see FIG. 9) to indicate the speaker layer number serves as an example of the “layer information to indicate a total number of planes with different heights from each other allowing a three dimensional arrangement of speakers” according to the present invention.

On the other hand, the “layer constitution (layer T, layer M, layer F)” herein means whether or not any channel corresponding to a speaker arrangement including at least one speaker disposed therein exists in each layer. That is, the information to indicate the layer constitution uses 3 bits among the upper 4 bits in FIG. 9, to indicate by using 1 bit whether or not each layer has a channel structure corresponding to a speaker arrangement including at least one speaker disposed therein. For example, if 1 bit value of the “layer T” in FIG. 9 is “1b”, it indicates that the layer has a channel structure corresponding to a speaker arrangement including at least one speaker disposed therein at the ceiling level. If 1 bit value of the “layer M” in FIG. 9 is “1b”, it indicates that the layer has a channel structure corresponding to a speaker arrangement including at least one speaker disposed therein at the mid level. If 1 bit value of the “layer F” in FIG. 9 is “1b”, it indicates that the layer has a channel structure corresponding to a speaker arrangement including at least one speaker disposed therein at the floor level.

Incidentally, a code “b” in the aforementioned bit value “xb” means that the value is based on binary notation (hereinafter the same).

Thus in this example, 3 bits in the upper 4 bits of the layer layout information (see FIG. 9) serves as an example of the “layer constitution information to indicate whether or not at least one speaker is disposed on each plane “according to the present invention”.

Incidentally, whether or not a plurality of mid level layers exists is judged by referring to the speaker layer number. For example, two mid level layers exist and a floor level layer exists, the layer T becomes “0b”, the layer M becomes “1b” and the layer F becomes “1b”, and the speaker layer number becomes “3”. Therefore, subtracting the floor level layer number “1” from the speaker layer number “3” reveals that the mid layers number is “2”.

The channel assignment #j (Ch Asn j) information has a field size of 4 bytes, and records a speaker plane arrangement for each layer such as the floor level, the mid level and the ceiling level whose existence is indicated by the layer layout information, as exemplified in FIG. 10 for example.

Particularly in this example as shown in FIG. 10, the channel assignment #j information as an example of the “channel assignment information” according to the present invention is constructed as the channel assignment table. The arrangement of FIG. 10 has a bit arrangement similar to the first embodiment shown in FIG. 1. That is, the bit arrangement (row) of the first byte designated by RBP#1 corresponds to a front side of the speaker arrangement on the basis of the audience, the bit arrangement (row) of the second byte designated RBP#2 corresponds to a mid toward front side of the speaker arrangement (a side speaker arrangement toward the front side) on the basis of the audience, the bit arrangement (row) of the third byte designated by RBP#3 corresponds to a mid toward rear side of the speaker arrangement (a side speaker arrangement toward the rear side) on the basis of the audience, and the bit arrangement (row) of the fourth byte designated by RBP#4 corresponds to a rear side of the speaker arrangement on the basis of the audience. In every row, the MSB side of the bit arrangement corresponds to a left side of the audience, while the LSB side of the bit arrangement corresponds to a right side of the audience. Furthermore, MSBs in every row are all reserved, while LSB in the first row is assigned for LFE and LSBs in the second to fourth rows are reserved.

In FIG. 10, the code “L” means that the corresponding speaker is positioned at the left side or toward the left side, the code “R” means that the corresponding speaker is positioned at the right side or toward the right side, the code “f” means that the corresponding speaker is positioned at the front side or toward the front side, and the code “r” means that the corresponding speaker is positioned at the rear side or toward the rear side. Furthermore, the code “m” means that the corresponding speaker is positioned near the mid point along a back-and-forth direction, and the code “middle” means that the corresponding speaker is positioned near the mid point along a right-left direction. Furthermore, the code “C” means that the corresponding speaker is positioned at center of the right-left direction. Additionally, “LFE” means a channel compatible with a super woofer speaker, and “reserved” means that it is reserved for an expanded use.

Therefore, in FIG. 10, for example “Lf” corresponds to a channel for a speaker positioned at a left front side, “Rf” corresponds to a channel for a speaker positioned at a right front side, “Lr” corresponds to a channel for a speaker positioned at a left rear side, “Rr” corresponds to a channel for a speaker positioned at a right rear side, “Cf” corresponds to a channel for a speaker positioned at a central front side and “Cr” corresponds to a channel for a speaker at a central rear side.

Thus, the channel assignment table as shown in FIG. 10 is a table corresponding to an actual speaker plane arrangement. In the case that the sound data of channel corresponding to each speaker arrangement exists, the bit in the table corresponding to the speaker arrangement is “1b” (as mentioned above, however, “b” is a code signifying the binary notation). On the contrary, in the case that the sound data of channel corresponding to each speaker arrangement does not exist, the bit in the table corresponding to the speaker arrangement is “0b”. Furthermore, reserved fields or reserved bits are all “0b”.

Incidentally, bits as many as the total channel number of title #i recorded in the channel number information exemplified in FIG. 8 are designated as “1b” in the channel assignment table.

For example, with regard to the sound data of 2 channel stereo, i.e. the sound data of only Lf and Rf, a value “01000100b(44h)” is recorded for the first row, values “00000000b(00h)” are recorded for the second to fourth rows in the channel assignment table indicating the channel assignment. Furthermore, for example, in the case of 5.1 surround channel sound data, i.e. the sound data of only 6 channels including Lf, Rf, C, Lr, Rr and LFE, a value “01010101b(55b)” is recorded for the first row, values “00000000b(00b)” are recorded for the second and third rows, and a value 01000100b(44h)” is recorded for the fourth row in the channel assignment table indicating the channel assignment.

Particularly in this example, similarly to the aforementioned way, it is possible to assign the channel even for a 3D speaker arrangement as shown in the second embodiment with reference to FIG. 2, by preparing channel assignment tables shown in FIG. 10 for each level including the floor level, the mid level and the ceiling level. That is, in theory, the assignment rule similar to the aforementioned rule is applicable, as long as the channel assignment table is incremented by 1, as the layer (level) is incremented by 1. Thus, this present example provides a remarkable flexibility in the height direction of the speaker arrangement.

In the case of handling a plurality of levels, the first channel assignment #1 information (see FIG. 5) is firstly assigned to the floor level layer. If the floor level does not exist, the first channel assignment #1 information (see FIG. 5) can be assigned to a level layer nearest the floor. Alternatively, the first channel assignment #1 information (see FIG. 5) may be assigned to the ceiling level layer. In theory, regardless of how many mid level layers exist, the first channel assignment #1 information (see FIG. 5) may be assigned to the floor level layer, and the last channel assignment #m information may be assigned to the ceiling level layer, so that the assignment rule as aforementioned is directly used to address a complicated 3D speaker arrangement.

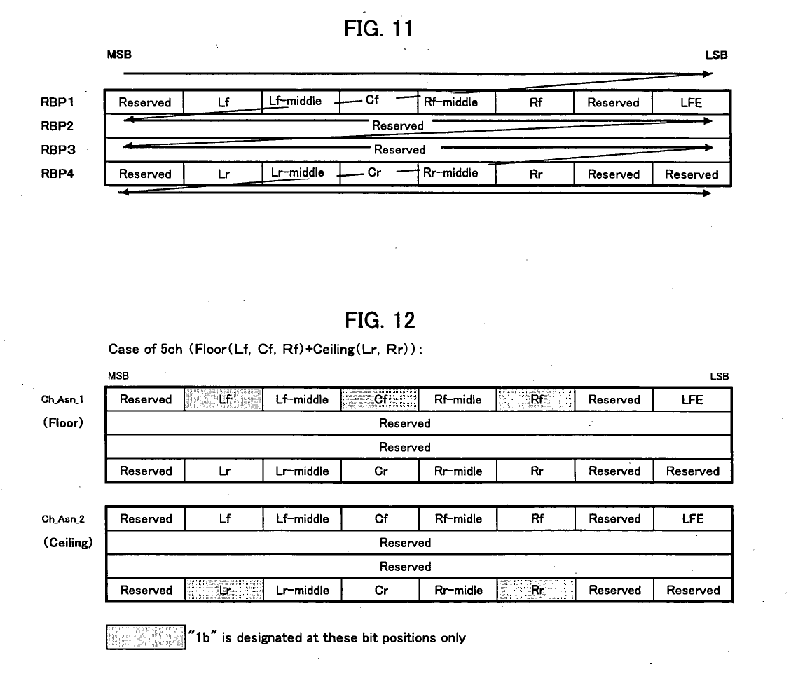

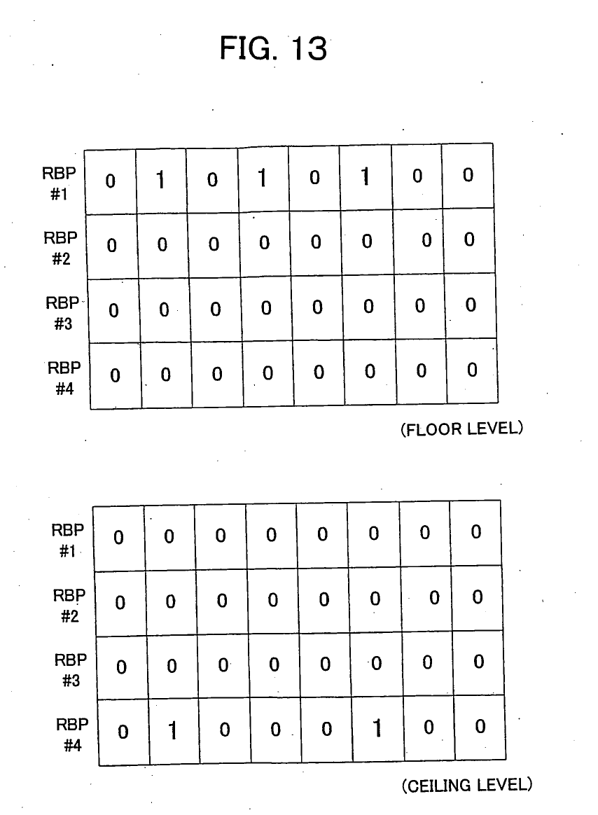

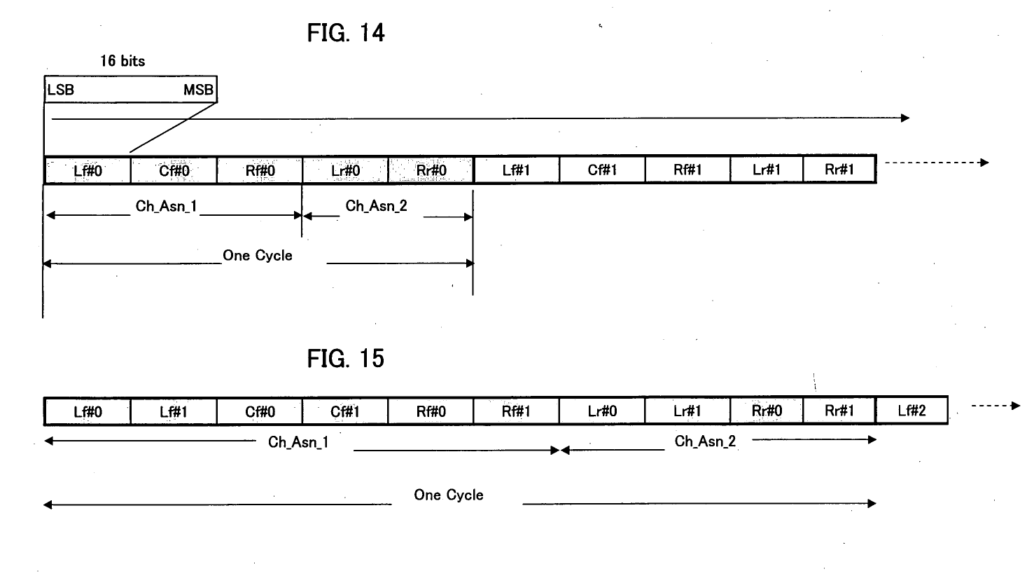

Now, with reference to FIG. 11 to FIG. 15, an explanation will be made on a specific example of the audio data arrangement recorded in the data record area as a stream data. FIG. 11 illustrates conceptually illustrates a recording sequence of the sample data of the audio data, in association with bit arrangements on the channel assignment table. FIG. 12 conceptually illustrates a specific example of the channel assignment table for the floor level and the channel assignment table for the ceiling level. FIG. 13 conceptually illustrates actual bit arrangements in two channel assignment tables shown in FIG. 12. FIG. 14 conceptually illustrates a data structure of the sample data in this specific example, when it is arranged as a stream data in the data record area. FIG. 15 conceptually illustrates a data structure in the modified example.

The “sample data” herein is referred to a unit of data which results from sampling the sound data for each channel as digital data in quantization bit number (e.g. 16 bits, 20 bits, 24 bits and so on) for every sampling period. In the case of the sound data for a plurality of channels, since they are need to be reproduced at the same time on reproduction, the sample data of each channel is arranged alternately or telescopically in the stream data.

The sample data of each channel is arranged and recorded in the stream data, in a sequence shown by an arrow in FIG. 11 for example. That is, they are arranged in the sequence of (i) MSB to LSB of the first row designated RBP#1, (ii) MSB to LSB of the second row designated RBP#2, (iii) MSB to LSB of the third row designated RBP#3, and (iv) MSB to LSB of the fourth row designated RBP#4. In general, however, all bits are not always designated as “1b” in the channel assignment table. Therefore, only the sample data of channels whose existence is indicated by these bits is arranged in the data stream so as not to remain the vacant space.

As exemplified in the channel assignment table in FIG. 12, it is assumed that the sound data for three channels, Lf, Cf and Rf exists for the floor level and the sound data for two channels, Lf and Rf exists for the ceiling level, that is a case of 5 channels in total.

In this case, as shown in FIG. 13, only bits of LF, Cf and Rf are designated respectively as “1b” in the channel assignment table for the floor level (see upper part of FIG. 13), and only bits of Lf and Rf are designated as “1b” in the channel assignment table for the ceiling level.

Two channel assignment tables shown in FIG. 12 and FIG. 13 correspond to the channel assignment #1 (Ch Asn 1) information and the channel assignment #2 (Ch Asn 2) (sic) shown in FIG. 5. In the case that two channel assignment tables exits as mentioned above, one stream data is formed by firstly arranging each channel on the floor level in the sequence shown in FIG. 11, and then arranging each channel on the ceiling level in the sequence shown in FIG. 11.

With regard to the sound data having the channel structure shown in FIG. 12 and FIG. 13, arranging the sound data of each channel as the stream data in the sequence shown by the arrow in FIG. 11 provides the data arrangement shown in FIG. 14. That is, in one cycle of the sound data part of each channel reproduced at the same time, the sample data of each channel is arranged in the sequence of sample data Lf#0, sample data Cf#0, sample data Rf#0, sample data Lr#0, and sample data Rr#0, for the sampling timing #0 for example. Then, with regard to sampling timing #1, the sample data of each channel is arranged in the sequence of sample data Lf #1, sample data Cf#1, sample data Rf#1, sample dataLr#1, and sample data Rr#1. Then, such a cycle is repeated along the reproduction time axis, for each sampling timing #0, #1, . . . .

Incidentally, in FIG. 14, each sample data has the size of 16 bits. Nevertheless, it may be 20 bits, 24 bits and so on, which can be reproduced without any problem, insofar as the recording and reproduction is performed on the basis of this value, which is recorded in the quantization bit number information (see FIG. 5) in the title information 114 mentioned above. Furthermore, the codec is not limited to the specific example.

As a modified example shown in FIG. 15, it is possible to arrange as a stream data for each sample data relating to two sampling timing (e.g. sample timing #0&#1, sample timing #2&#3, and so on). The sampling cycle is usually so short that a particular problem does not arise by slightly increasing the buffer for the sound data on the reproduction, even in the case that two sets of sample data whose reproduction time is not the same but consecutive are recorded. Furthermore, it is possible to record two or more sample data for each channel, insofar as it is within time period capable of being handled by the buffer on the reproduction.

Additionally, in these specific examples, the sound data for channels on the floor level side is firstly arranged and then the sound data for channels on the ceiling level side is arranged. Nevertheless this sequence may be inverted. Furthermore, the orientation of the arrow shown in FIG. 11 may be of a direction from left to right (LSB to MSB), or may be of a direction from lower to upper (RPB#4 to RPB#1). In short, any sequence may be taken, insofar as it is possible to identify a rule to assign the sequence on the channel assignment table to the sequence of the sample data arrangement in the stream data.

As mentioned above, according to this example, it is easy to determine a desired speaker configuration or channel configuration by means of two dimensional bit arrangement in the channel assignment table, as in FIG. 10, without defining the way of arranging data for each channel configuration typically as seen in the conventional channel assignment. That is, it is sufficient to set a bit only at a speaker position of an existing channel, in a channel assignment table corresponding to an actual plane configuration as shown in FIG. 13. Furthermore, also for the sample data arrangement, as shown in FIG. 14 and FIG. 15, it is sufficient to arrange only the sample data whose existence is indicated by the channel assignment table according to a predetermined rule, without defining a special bit arrangement for each channel.

Furthermore, with regard to an expansion of the speaker arrangement on a plane, it is sufficient to change a bit number of one row or a row number of the two dimensional bit arrangement constituting a channel assignment table. The expansion is easy in longitude and transverse directions.

Additionally, associating such a channel assignment table with planes with different levels from each other makes it possible to expand in a height direction, without introducing a new definition method in particular. That is, it is easy to handle the 3D speaker arrangement, almost the same as the 2D speaker arrangement. In this case, the required information is relatively less, and there is no need to define a complicated data arrangement method for each channel configuration corresponding to speakers three dimensionally arranged.

(Example of Information Record Reproduction Apparatus)

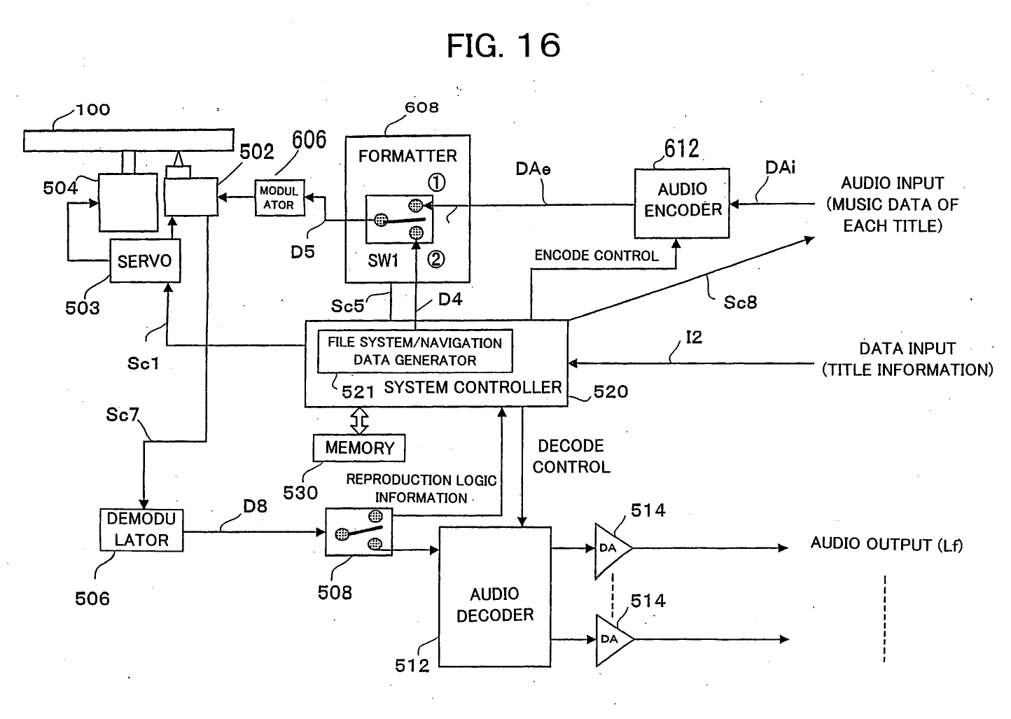

Now, an explanation will be made on an example of the information record reproduction apparatus according to the present invention, with reference to FIG. 16. FIG. 16 shows an information record reproduction apparatus in a block diagram.

In FIG. 16, the information record reproduction apparatus is mainly made of a reproduction system and a record system, and adapted to record information into the aforementioned optical disc 100 and reproduce the information recorded therein. In this example, the information record reproduction apparatus is for recording and reproducing. Nevertheless, basically, this record system can provide an example of the record apparatus according to the present invention, and on the other hand, this reproduction system can provide an example of the information reproduction apparatus according to the present invention.

The information record reproduction apparatus is provided with: an optical pickup 502; a servo unit 503; a spindle motor 504; a demodulator 506; a shift switch 508; an audio decoder 512; a channel-based DA(digital/analog) converter 514; a system controller 520; a memory 530; a modulator 606; a formatter 608; and an audio encoder 612. The system controller 520 includes a file system/navigation data generator 521.

Among these constitutional elements, the demodulator 506, the shift switch 508, the audio decoder 512 and the DA converter 514 mainly constitute the reproduction system. On the other hand, among these constitutional elements, the modulator 602, the formatter 608 and the audio encoder 612 mainly constitute the record system. The optical pickup 502, the servo unit 503, the spindle motor 504, the system controller 520 and the memory 530 are generally used for both the reproduction system and the record system. The file system/navigation data generator 521 provided in the system controller 520 is used mainly for the record system.

The optical pickup 502 irradiates the optical disc 100 with light beam LB such as laser beam having the first power as the reading light for the reproduction, and irradiates the optical disc 100 with light beam LB such as laser beam, which is modulated, having the second power as the writing light for the recording. The servo unit 503 performs a focus servo, a tracking servo for the optical pickup 502, and performs a spindle servo for the spindle motor 504, under control of a control signal Sc1 outputted from the system controller 520 on the reproduction and the recording. The spindle motor 504 is adapted to rotate the optical disc 100 at a predetermined speed, under the spindle servo of the servo unit 503.

(i) Structure and Operation of Reproduction System

Now, with reference to FIG. 16, an explanation will be made on a specific structure of constitutional elements constituting the reproduction system of the information record reproduction apparatus and the operation thereof.

By means of a user interface, the title information to indicate a title to be reproduced from the optical disc 100, further the reproduction condition and so on are inputted as a data input I2 into the system controller 520. In this case, the user interface (not shown) is adapted to allow an input operation suitable for the to-be-reproduced contents, such as a selection via a title menu screen, under control of the system controller 520.

In response to the input, the system controller 520 controls the disc reproduction of the optical disc 100, and the optical pickup 502 transmits a reading signal S7 to the demodulator 506.

The demodulator 506 decodes the recording signal recorded in the optical disc 100 from this reading signal S7, and outputs it as the decoded data D8. A logic information file 110 (see FIG. 4) included in this decoded data D8 is supplied as “reproduction logic information” to the system controller 520 by a switching operation of the shift switch 508. On the basis of various kinds of logic information in the logic information file 110, the system controller 520 performs various reproduction controls such as a determination of a reproduction address, a control of the optical pickup 502 and so on.

On the other hand, the sound data included in the decoded data D8 is supplied to the audio decoder 512 by a switching operation of the shift switch.

The audio decoder 512 decodes the sound data for each channel, under a decode control of the system controller 520 based on various kinds of logic information in the logic information file 110. The DA converter 514 performs a digital-analog conversion, an amplification and so on for each channel, so that the audio data may be outputted to an external speaker for example.

In this case, particularly in this example, the system controller 520 refers to a channel assignment table (see FIG. 12, FIG. 13 and so on) included in the logic information file 110 to identify easily which sample data of the sound data (see FIG. 14 and FIG. 15) for a plurality of channels decoded as a stream data at the demodulator 506 is originated from sound data of which channel. Therefore, under control of the system controller 520, the audio decoder 512 can decodes sound data of each channel for each channel, and output it to the DA converter 514 for each channel.

As the result, the sound data recorded in the optical disc 100 for multi-channels corresponding to a complicated speaker arrangement arranged two or three dimensionally can be appropriately reproduced by the information record reproduction apparatus.

Incidentally, it is often happen that the DA converter 514 of the information record reproduction apparatus and the external speaker and the like does not have a reproduction ability sufficient to the sound data for multi-channels recorded in the optical disc 100. In such a case, however, using various known downmixing techniques makes it possible to mixdown the sound data for multi-channels reproduced from the optical disc 100 to the sound data reproducible with the information record reproduction apparatus including the external speaker and the like, according to a predetermined rule.

(ii) Structure and Operation of Record System

Now, with reference to FIG. 16, an explanation will be made on a specific structure of constitutional elements constituting the record system of the information record reproduction apparatus and the operation thereof.

Firstly, via the interface (not shown), the user input I2 such as the to-be-recorded title information is inputted into the system controller 520. In this case, the user interface is adapted to perform an input operation suitable for the to-be-recorded contents such as a selection via a title menu screen, under control of the system controller 520.

Next, the sound data such as music data of each title is inputted, under control of a control signal Sc8 from the system controller 520 to instruct the data reading. In this case, the sound data DAi is inputted from an external source.

The audio encoder 612 encodes the inputted sound data DAi, under encode control of the system controller 520 based on the user input I2. The encoding scheme in this case may be of various kinds. Then, it is outputted as the encoded sound data DAe.

On the other hand, the system controller 520 controls the file system/navigation data generator 521 to generate various kinds of logic information as shown in FIG. 5 and output it as the logic information D4, according to the contents of the user input I2, or instead of or in addition to this and according to an analysis result of the contents of the sound data DAi which is taken.

The formatter 608 is a device for performing a data arrangement format to store the sound data DAe and the logic information D4 onto the optical disc 100. More specifically, the formatter 608 has a switch Sw1, which is connected to \mathring{1} side to output the sound data DAe as formatted disc image data D5 in formatting the sound data DAe, under switching control of a switch control signal Sc5 from the system controller 520. Incidentally, output control of the sound data DAi is performed under control of a control signal Sc8 from the system controller 520.

On the other hand, the switch Sw1 of the formatter 608 is shifted to \mathring{2} side to output the logic information D4 as disc image data D5 in formatting the logic information D4, under switching control of the switch control signal Sc5 from the system controller 520.

The modulator 606 modulates the disc image data D5 from the formatter 608 and records it onto the optical disc 100 via the optical pickup 502. In this case, disc recording control is also performed by the system controller 520.

As the result, the sound data for multi-channels corresponding to a complicated speaker arrangement arranged two or three dimensionally can be appropriately recorded with the channel assignment table mentioned above and the like onto/into the optical disc 100 by the information record reproduction apparatus.

Incidentally, the to-be-recorded sound data DAi may be sound data received via a communication network or communication wave for example, or may be sound data recorded in another record medium, or may be sound data generated from a microphone. The type or kind does not matter.

In each example mentioned above, the sound data may be packed or packetized by means of a suitable size pack or packet such as 2048 kbytes or the like. Arranging the sample data in each packet as exemplified in FIG. 14 and FIG. 15 makes it possible to perform the recording and reproduction while obtaining the benefit of the channel assignment information similarly to various examples mentioned above. For example, the sound data may be multi-recorded onto a disc in a program stream scheme of MPEG2 (Moving Picture Experts Group phase 2) standard, or may be multi-recorded onto a disc in a transport stream scheme of MPEG2 standard. Furthermore, the sound data may be multiplexed with various data such as video data, sub-picture data, computer record data, program data and so on.

Incidentally, in the aforementioned example, an explanation has been made on the optical disc 100 as an example of the information record medium, and a recorder or player for the optical disc 100, as an example of the information record reproduction apparatus. Nevertheless, the present invention is not limited to the optical disc, nor to the recorder or player therefore, but may be applicable to various information record medium compatible with other types of high density recording or high transfer rate, and the recorder or player thereof.

As mentioned above, according to various embodiments of the present invention, the channel assignment table and so on is recorded into/onto the optical disc 100. The information record reproduction apparatus includes the system controller 520 to generate such a channel assignment table for the recording, and identify the channel assignment on the basis of the channel assignment information like this for the reproduction. Therefore, various examples of the present invention provide the remarkable flexibility in kinds of the speaker arrangement capable of being handled, such as a complicated speaker arrangement two or three dimensionally arranged.

The present invention is not limited to the aforementioned examples, but can be modified or changed within a range without departing from the spirit or essence of the present invention read from the whole specification and the claims. The information record medium, the information record apparatus and method, the information reproduction apparatus and method, the information record reproduction apparatus and method, the computer program for recording or reproduction control, and the data structure including the control signal, involving such a modification or change are also encompassed within a scope of the invention.

### IDUSTRIAL APPLICABILITY

The information record medium, the information record apparatus and method, the information reproduction apparatus and method, the information record reproduction apparatus and method, the computer program, and the data structure according to the present invention are applicable to optical discs for example for recording or reproducing multi-channel audio data for consumer or industrial use. Furthermore, they are applicable to information record medium, information record reproduction apparatuses and the like mounted on or connectable to various computer devices for consumer or industrial use for example.

1-27. (canceled)

28. An information record medium on which reproduction control information including channel assignment information in which each bit position in a bit arrangement made of a plurality of bits is assigned to each channel corresponding to each speaker position in a speaker arrangement made of a plurality of speakers, so that each bit value indicates whether or not audio data for each channel corresponding to each bit exists, and
a plurality of audio data whose existence is indicated by the channel assignment information and recorded for each channel are recorded.

29. The information record medium according to claim 28, wherein the channel assignment information comprises a channel assignment table in which the speaker arrangement is associated with the bit arrangement.

30. The information record medium according to claim 28, wherein the plurality of audio data is packed or packetized, and arranged in a sequence corresponding to an arrangement sequence of the plurality of bits by one or more sample units in each pack or each packet.

31. The information record medium according to claim 28, wherein a bit existing at a predetermined position in the bit arrangement indicates whether or not audio data for any channel not corresponding to a speaker position in the speaker arrangement exists.

32. The information record medium according to claim 31, wherein the bit existing at the predetermined position is an LSB (Least Significant Bit) in the bit arrangement and indicates whether or not audio data for a super woofer channel exists.

33. The information record medium according to claim 28, wherein
the bit arrangement is made of a plurality of bits arranged two dimensionally with a predetermined number of bits for each row over a predetermined number of rows,
the speaker arrangement is made of a plurality of speakers arranged on a plane corresponding to the two dimensional arrangement of the plurality of bits.

34. The information record medium according to claim 28, wherein
the speaker arrangement is made of a plurality of speakers arranged three dimensionally,
the bit arrangement includes a plurality of partial bit arrangements,
each of the plurality of partial bit arrangements is made of a plurality of bits arranged two dimensionally with a predetermined number of bits for each row over a predetermined number of rows, each partial bit arrangement being associated with a plurality of channels corresponding to a plurality of speakers arranged on a plane of the same height for each concerned partial bit arrangement, from among the plurality of speakers arranged three dimensionally,
the plurality of partial bit arrangements exist as many as the number of the planes.

35. The information record medium according to claim 34, wherein the reproduction control information further includes total channel number information to indicate a total channel number, layer information to indicate a total number of planes having different heights from each other allowing a three dimensional arrangement of speakers, and layer constitution information to indicate whether or not at least one speaker is disposed on each plane.

36. The information record medium according to claim 33, wherein at least one of the predetermined number of bits or the predetermined number of rows is variable.

37. An information record apparatus comprising:
a generating device for generating reproduction control information including channel assignment information in which each bit position in a bit arrangement made of a plurality of bits is assigned to each channel corresponding to each speaker position in a speaker arrangement made of a plurality of speakers, so that each bit value indicates whether or not audio data for each channel corresponding to each bit exists; a first recording device for recording the generated reproduction control information into a control information area on an information record medium; and
a second recording device for recording a plurality of audio data whose existence is indicated by the channel assignment information into a data area on the information record medium for each channel.

38. The information record apparatus according to claim 37, wherein the channel assignment information comprises a channel assignment table in which the speaker arrangement is associated with the bit arrangement.

39. The information record apparatus according to claim 37, wherein the plurality of audio data is packed or packetized, and arranged in a sequence corresponding to an arrangement sequence of the plurality of bits by one or more sample units in each pack or each packet.

40. The information record apparatus according to claim 37, wherein a bit existing at a predetermined position in the bit arrangement indicates whether or not audio data for any channel not corresponding to a speaker position in the speaker arrangement exists.

41. The information record apparatus according to claim 40, wherein the bit existing at the predetermined position is an LSB (Least Significant Bit) in the bit arrangement and indicates whether or not audio data for a super woofer channel exists.

42. The information record apparatus according to claim 37, wherein
the bit arrangement is made of a plurality of bits arranged two dimensionally with a predetermined number of bits for each row over a predetermined number of rows,
the speaker arrangement is made of a plurality of speakers arranged on a plane corresponding to the two dimensional arrangement of the plurality of bits.

43. The information record apparatus according to claim 37, wherein
the speaker arrangement is made of a plurality of speakers arranged three dimensionally,
the bit arrangement includes a plurality of partial bit arrangements,
each of the plurality of partial bit arrangements is made of a plurality of bits arranged two dimensionally with a predetermined number of bits for each row over a predetermined number of rows, each partial bit arrangement being associated with a plurality of channels corresponding to a plurality of speakers arranged on a plane of the same height for each concerned partial bit arrangement, from among the plurality of speakers arranged three dimensionally,
the plurality of partial bit arrangements exists as many as the number of the planes.

44. The information record apparatus according to claim 43, wherein the reproduction control information further includes total channel number information to indicate a total channel number, layer information to indicate a total number of planes having different heights from each other allowing a three dimensional arrangement of speakers, and layer constitution information to indicate whether or not at least one speaker is disposed on each plane.

45. The information record apparatus according to claim 42, wherein at least one of the predetermined number of bits or the predetermined number of rows is variable.

46. An information record method comprising:
a generating process of generating reproduction control information including channel assignment information in which each bit position in a bit arrangement made of a plurality of bits is assigned to each channel corresponding to each speaker position in a speaker arrangement made of a plurality of speakers, so that each bit value indicates whether or not audio data for each channel corresponding to each bit exists; a first recording process of recording the generated reproduction control information into a control information area on an information record medium; and
a second recording process of recording a plurality of audio data whose existence is indicated by the channel assignment information into a data area on the information record medium for each channel.

47. An information reproduction apparatus for reproducing a plurality of audio data from an information record medium on which reproduction control information including channel assignment information in which each bit position in a bit arrangement made of a plurality of bits is assigned to each channel corresponding to each speaker position in a speaker arrangement made of a plurality of speakers, so that each bit value indicates whether or not audio data for each channel corresponding to each bit exists, and the plurality of audio data whose existence is indicated by the channel assignment information and recorded for each channel are recorded, said information reproduction apparatus comprising:
a reading device for reading the plurality of audio data and the reproduction control information from the information record medium;
an identifying device for identifying channels of the plurality of audio data recorded in the information record medium, on the basis of each bit position in the bit arrangement relating to the channel assignment information included in the read reproduction control information; and
a reproducing device for reproducing the plurality of read audio data as a plurality of audio data for the identified each channel.

48. An information reproduction method of reproducing a plurality of audio data from an information record medium on which reproduction control information including channel assignment information in which each bit position in a bit arrangement made of a plurality of bits is assigned to each channel corresponding to each speaker position in a speaker arrangement made of a plurality of speakers, so that each bit value indicates whether or not audio data for each channel corresponding to each bit exists, and the plurality of audio data whose existence is indicated by the channel assignment information and recorded for each channel are recorded, said information reproduction method comprising:
a reading process of reading the plurality of audio data and the reproduction control information from the information record medium;
an identifying process of identifying channels of the plurality of audio data recorded in the information record medium, on the basis of each bit position in the bit arrangement relating to the channel assignment information included in the read reproduction control information; and
a reproducing process of reproducing the plurality of read audio data as a plurality of audio data for the identified each channel.

49. An information record reproduction apparatus comprising:
a generating device for generating reproduction control information including channel assignment information in which each bit position in a bit arrangement made of a plurality of bits is assigned to each channel corresponding to each speaker position in a speaker arrangement made of a plurality of speakers, so that each bit value indicates whether or not audio data for each channel corresponding to each bit exists; a first recording device for recording the generated reproduction control information into a control information area on an information record medium;
a second recording device for recording a plurality of audio data whose existence is indicated by the channel assignment information into a data area on the information record medium for each channel;
a reading device for reading the plurality of audio data and the reproduction control information from the information record medium;
an identifying device for identifying channels of the plurality of audio data recorded in the information record medium, on the basis of each bit position in the bit arrangement relating to the channel assignment information included in the read reproduction control information; and
a reproducing device for reproducing the plurality of read audio data as a plurality of audio data for the identified each channel.

50. An information record reproduction method comprising:
a generating process of generating reproduction control information including channel assignment information in which each bit position in a bit arrangement made of a plurality of bits is assigned to each channel corresponding to each speaker position in a speaker arrangement made of a plurality of speakers, so that each bit value indicates whether or not audio data for each channel corresponding to each bit exists; a first recording process of recording the generated reproduction control information into a control information area on an information record medium;
a second recording process of recording a plurality of audio data whose existence is indicated by the channel assignment information into a data area on the information record medium for each channel;
a reading process of reading the plurality of audio data and the reproduction control information from the information record medium;
an identifying process of identifying channels of the plurality of audio data recorded in the information record medium, on the basis of each bit position in the bit arrangement relating to the channel assignment information included in the read reproduction information; and
a reproducing process of reproducing the plurality of read audio data as a plurality of audio data for the identified each channel.

51. A computer program product for a recording control to control a computer provided for an information record apparatus comprising: a generating device for generating reproduction control information including channel assignment information in which each bit position in a bit arrangement made of a plurality of bits is assigned to each channel corresponding to each speaker position in a speaker arrangement made of a plurality of speakers, so that each bit value indicates whether or not audio data for each channel corresponding to each bit exists; a first recording device for recording the generated reproduction control information into a control information area on an information record medium; and a second recording device for recording a plurality of audio data whose existence is indicated by the channel assignment information into a data area on the information record medium for each channel, and to make the computer function as at least part of the generating device, the first recording device and the second recording device.

52. A computer program product for a reproduction control to control a computer provided for an information reproduction apparatus for reproducing a plurality of audio data from an information record medium on which reproduction control information including channel assignment information in which each bit position in a bit arrangement made of a plurality of bits is assigned to each channel corresponding to each speaker position in a speaker arrangement made of a plurality of speakers, so that each bit value indicates whether or not audio data for each channel corresponding to each bit exists, and the plurality of audio data whose existence is indicated by the channel assignment information and recorded for each channel are recorded, said information reproduction apparatus comprising: a reading device for reading the plurality of audio data and the reproduction control information from the information record medium; an identifying device for identifying channels of the plurality of audio data recorded in the information record medium, on the basis of each bit position in the bit arrangement relating to the channel assignment information included in the read reproduction control information; and a reproducing device for reproducing the plurality of read audio data as a plurality of audio data for the identified each channel, and to make the computer function as at least part of the reading device, the identifying device and the reproducing device.

53. A computer program product for a recording and reproduction control to control a computer provided for an information record reproduction apparatus comprising: a generating device for generating reproduction control information including channel assignment information in which each bit position in a bit arrangement made of a plurality of bits is assigned to each channel corresponding to each speaker position in a speaker arrangement made of a plurality of speakers, so that each bit value indicates whether or not audio data for each channel corresponding to each bit exists; first recording device for recording the generated reproduction control information into a control information area on an information record medium; a second recording device for recording a plurality of audio data whose existence is indicated by the channel assignment information into a data area on the information record medium for each channel; a reading device for reading the plurality of audio data and the reproduction control information from the information record medium; an identifying device for identifying channels of the plurality of audio data recorded in the information record medium, on the basis of each bit position in the bit arrangement relating to the channel assignment information included in the read reproduction control information; and a reproducing device for reproducing the plurality of read audio data as a plurality of audio data for the identified each channel, and to make the computer function as at least part of the generating device, the first recording device, the second recording device, the reading device, the identifying device and the reproducing device.

54. A data structure including a control signal, said structure comprising:
reproduction control information including channel assignment information in which each bit position in a bit arrangement made of a plurality of bits is assigned to each channel corresponding to each speaker position in a speaker arrangement made of a plurality of speakers, so that each bit value indicates whether or not audio data for each channel corresponding to each bit exists, and
a plurality of audio data whose existence is indicated by the channel assignment information and recorded for each channel.
